(19) United States
(12) Patent Application Publication
(10) Pub. No.: US 2011/0024879 A1
(43) Pub. Date: Feb. 3, 2011

(54) METHOD TO REDUCE PRE-ALIGNMENT ERROR USING MULTI-NOTCH PATTERN OR IN COMBINATION WITH FLAT SIDE

(75) Inventor: Sophia WANG, Xin-Zhu City (TW)

Correspondence Address: Lowe Hauptman Ham & Berner, LLP (TSMC), 1700 Diagonal Road, Suite 300, Alexandria, VA, 22314, US

(73) Assignee: TAIWAN SEMICONDUCTOR MANUFACTURING COMPANY, LTD., Hsinchu (TW)

(21) Appl. No.: 12/783,719

(22) Filed: May 20, 2010

Related U.S. Application Data
(60) Provisional application No. 61/229,249, filed on Jul. 28, 2009.

(51) Int. Cl. H01L 23/544; H01L 21/68

(52) U.S. Cl. 257/618; 414/816; 257/E23.179

(57) ABSTRACT

A semiconductor wafer has a pre-alignment pattern including two or more notches on the wafer edge and the notches are used for wafer pre-alignment in fabrication processes. In one embodiment, at least two distances along the wafer edge between any adjacent notches are different. In another embodiment, distances along the wafer edge between any adjacent notches are each different. In another aspect, the pre-alignment pattern includes one or more notches on the wafer edge and one flat side on the wafer edge, wherein the notches and the flat side are used for wafer pre-alignment in fabrication processes. In one embodiment, at least two distances along the wafer edge between any adjacent notches or between the flat side and an adjacent notch are different. In another embodiment, distances along the wafer edge between any adjacent notches and between the flat side and an adjacent notch are each different.

### CROSS-REFERENCE TO RELATED APPLICATIONS

The present application claims priority of U.S. Provisional Patent Application Ser. No. 61/229,249, filed on Jul. 28, 2009, which is incorporated herein by reference in its entirety.

### TECHNICAL FIELD

This invention relates generally to integrated circuit fabrication, more particularly semiconductor wafer pre-alignment method using notches and/or flat side.

### BACKGROUND

In integrated circuit fabrication, alignment is the step in a photolithographic process in which a mask used to pattern a layer of the circuit is registered in its x-y position with respect to the wafer (e.g., silicon) on which the circuit is being formed. By alignment, the mask (or reticle) in lithographic processes is positioned relative to a wafer prior to exposure of the resist. For this, the pattern on the mask is overlaid to the pattern previously created on the surface of the wafer. The pattern used for alignment is an alignment mark, which is a specially configured mark put on each mask in the set to allow precise alignment of the mask with pattern on the wafer.

Pre-alignment is a preliminary alignment (or coarse alignment) that is controlled by a simple mechanism, and it uses one notch or one flat side to make sure the wafers are on the correct position of machine chamber. Most machines in integrated circuit fabrication need to do the pre-alignment and the pre-alignment error can be several millimeters.

On the other hand, alignment in lithographic processes means a precise alignment (or fine alignment). Precise alignment needs to use some special layouts to collect the signal, and then makes some operational analyses by optical detector and software. Its error can be on the order of ten nanometers. The detector needs to be located in a correct range by pre-alignment; otherwise it leads to an alignment failure. From the viewpoint of lithographic process, “pre-alignment” is an important step for the final “alignment.”

For pre-alignment, typically a single-notch pattern is used for the wafer. A flat side can be also used, but a single-notch uses the area more efficiently. However, as the size of a wafer is increased for more efficient production of integrated circuit chips, the single-notch pattern has worse pre-alignment error with larger wafer size.

FIG. 1 illustrates the rotation error in a conventional wafer pre-alignment method using a single-notch pattern. The wafer 102 is shown with a single-notch pattern 104 for pre-alignment. For a given error angle θ, the rotation error length increases proportional to the diameter of the wafer 102. For example, when the wafer 102 has only a single notch, the machine has a worse pre-alignment error on an 18″ wafer than a 12″ wafer for a given error angle θ.

Accordingly, new methods for wafer pre-alignment in integrated circuit fabrication are desired to reduce the pre-alignment error.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 illustrates the rotation error in a conventional wafer pre-alignment method using a single-notch pattern;

FIG. 2 illustrates an exemplary multi-notch pattern on a wafer for pre-alignment according to one aspect of this invention;

FIG. 3A illustrates an exemplary single notch pattern in combination with one flat (or plane) side on a wafer for pre-alignment according to another aspect of this invention; and

FIG. 3B illustrates an exemplary multi-notch pattern in combination with one flat (or plane) side on a wafer for pre-alignment according to another aspect of this invention.

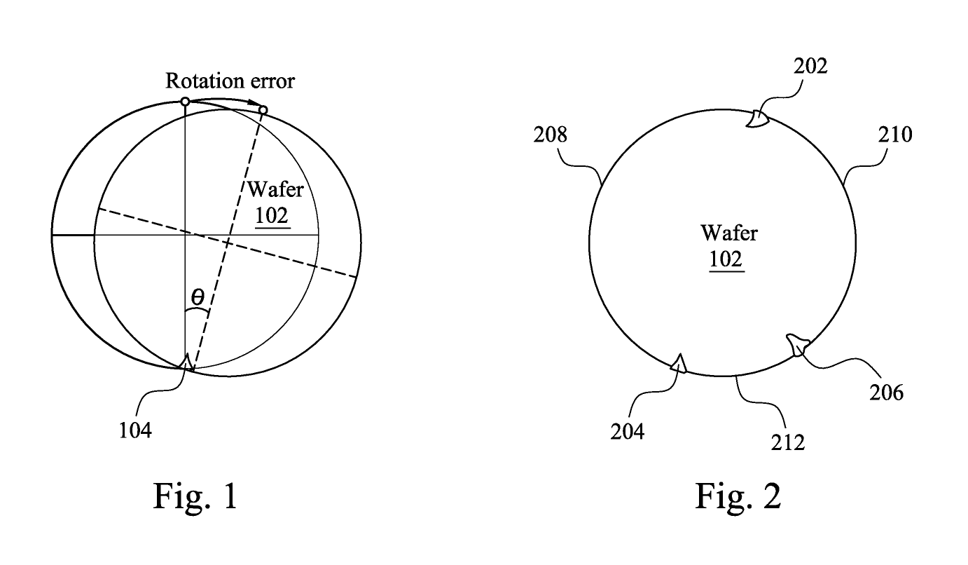

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

A method for wafer pre-alignment in integrated circuit fabrication to reduce the pre-alignment error is provided. Throughout the various views and illustrative embodiments of the present invention, like reference numbers are used to designate like elements.

FIG. 2 illustrates an exemplary multi-notch pattern for pre-alignment on a wafer according to one aspect of this invention. The three notches 202, 204, and 206 are spaced from each other to put them at the optimum location. More specifically, the distances along the wafer edge between any adjacent notches are not the same. That is, distance along the wafer edge 208 between notches 202 and 204 is not equal to the distance along the wafer edge 212 between notches 204 and 206, which is also not equal to the distance along the wafer edge 210 between notches 202 and 206.

In general, if there are N notches (1, 2, . . . , N) on the wafer for pre-alignment, then distance along the wafer edge between notches 1 and 2 is not equal to the distance along the wafer edge between notches 2 and 3 . . . is not equal to the distance along the wafer edge between notches N−1 and N and is not equal to the distance along the wafer edge between notches N and 1. This feature prevents pre-alignment errors from misidentifying one notch from another. However, in other embodiments, a portion of the distances between adjacent notches can be the same as long as the whole multi-notch pattern can be identified without pre-alignment error.

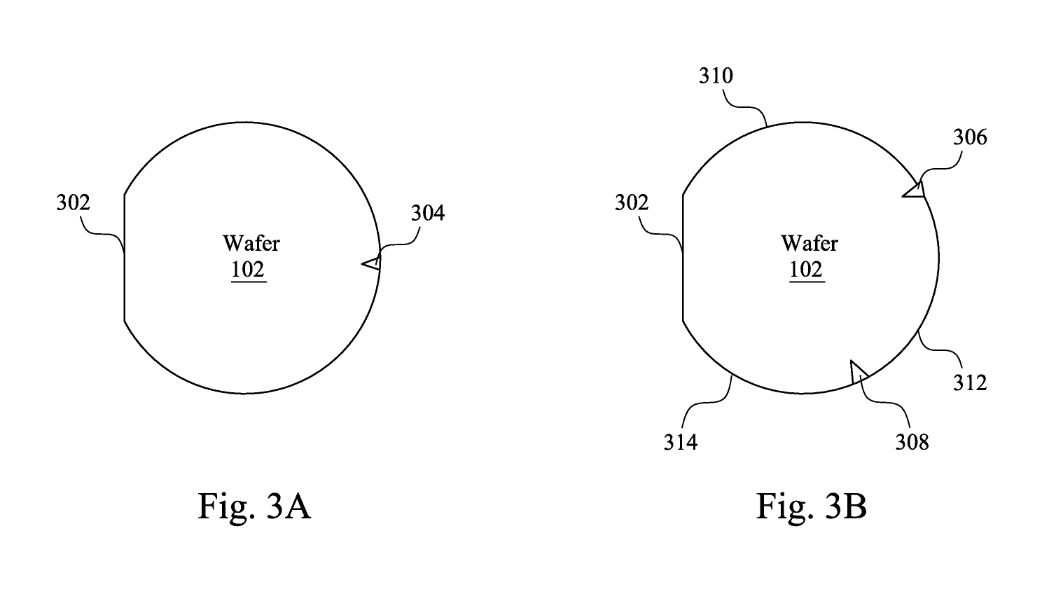

FIG. 3A illustrates an exemplary single notch pattern in combination with one flat (or planar) side on a wafer for pre-alignment according to another aspect of this invention. The flat side 302 feature is combined with a single notch 304 to help the correct pre-alignment of the wafer 102.

FIG. 3B illustrates an exemplary multi-notch pattern in combination with one flat (or plane) side on a wafer for pre-alignment according to another aspect of this invention. The flat side 302 is combined with two notches 306 and 308. Similar to FIG.

2, the distances along the wafer edge between any adjacent notches or a flat side are not the same. That is, distance along the wafer edge 312 between notches 306 and 308 is not equal to the distance along the wafer edge 310 between the flat side 302 and the notch 306, which is not equal to the distance along the wafer edge 314 between the flat side 302 and the notch 308.

In general, if there are N notches (1, 2, . . . , N) and a flat side on the wafer for pre-alignment, with the flat side adjacent to notches 1 and N, then distance along the wafer edge between notches 1 and 2 is not equal to the distance along the wafer edge between notches 2 and 3 . . . is not equal to the distance along the wafer edge between notches N−1 and N, which is not equal to the distance along the wafer edge between the flat side and the notch N, which is not equal to the distance along the wafer edge between the flat side and the notch 1. This feature prevents pre-alignment errors from misidentifying one notch from another. However, in other embodiments, a portion of the distances along the wafer edge between adjacent notches or a flat side can be the same, as long as the whole multi-notch pattern combined with a flat side can be correctly identified without pre-alignment error. Also, in another embodiment, multiple flat sides can be combined with multiple notches. A skilled person in the art will appreciate that there can be many embodiment variations of this invention.

The advantageous features of the present invention include reduction of the pre-alignment error by using multiple notches or in combination with a flat side. The correct position of notch can be recognized more easily by optimum distance design.

Although the present invention and its advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, and composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A semiconductor wafer with a pre-alignment pattern, the pre-alignment pattern comprising:
N notches on an edge of the semiconductor wafer, wherein N is an integer equal to or greater than 2.

2. The semiconductor wafer of claim 1, wherein at least two distances along the edge of the semiconductor wafer between any adjacent notches are different.

3. The semiconductor wafer of claim 1, wherein distances along the edge of the semiconductor wafer between any adjacent notches are each different.

4. A semiconductor wafer with a pre-alignment pattern, the pre-alignment pattern comprising:
N notches on an edge of the semiconductor wafer, wherein N is an integer equal to or greater than 1; and
one flat side on the edge of the semiconductor wafer.

5. The semiconductor wafer of claim 4, wherein at least two distances along the edge of the semiconductor wafer between any adjacent notches or between the flat side and an adjacent notch are different.

6. The semiconductor wafer of claim 4, wherein distances along the edge of the semiconductor wafer between any adjacent notches and between the flat side and an adjacent notch are each different.

7. A method for pre-aligning a semiconductor wafer, comprising:
providing the semiconductor wafer with N notches on an edge of the semiconductor wafer, wherein N is an integer equal to or greater than 2, and at least two distances along the edge of the semiconductor wafer between any adjacent notches are different; and
pre-aligning the semiconductor wafer using the notches in fabrication processes.

8. The method of claim 7, wherein distances along the edge of the semiconductor wafer between any adjacent notches are each different.

9. The method of claim 7, further comprising providing the semiconductor wafer with one flat side on the edge of the semiconductor wafer, wherein at least two distances along the edge of the semiconductor wafer between any adjacent notches or between the flat side and an adjacent notch are different.

10. The method of claim 9, wherein distances along the edge of the semiconductor wafer between any adjacent notches and between the flat side and an adjacent notch are each different.
